(19) United States
(12) Patent Application Publication
(10) Pub. No.: US 2017/0213653 A1
(43) Pub. Date: Jul. 27, 2017

(54) MULTILAYER THIN-FILM STRUCTURE, WATER SPLITTING SYSTEM USING THE SAME, AND METHOD OF FABRICATING MULTLAYER THIN-FILM STRUCTURE

(71) Applicant: FUJITSU LIMITED, Kawasaki-shi (JP)

(72) Inventors: John David Baniecki, Zama (JP); Takashi Yamazaki, Kawasaki (JP); Hiroyuki ASO, Atsugi (JP); Yoshihiko Imanaka, Atsugi (JP)

(73) Assignee: FUJITSU LIMITED, Kawasaki-shi (JP)

(21) Appl. No.: 15/408,614

(22) Filed: Jan. 18, 2017

(30) Foreign Application Priority Data
Jan. 22, 2016 (JP) 2016-011068

(51) Int. Cl. H01G 9/20; H01L 31/032; C25B 9/06; H01L 31/18; C25B 1/04; C25B 1/00; H01L 31/0445; H01L 31/072

(52) U.S. Cl. CPC H01G 9/2036; H01L 31/0445; H01L 31/032; H01L 31/072; H01L 31/18; C25B 1/04; C25B 1/003; C25B 9/06

(57) ABSTRACT

A multilayer thin-film structure has a layered structure with an alternative stacking series of a first layer of a first oxide semiconductor and a second layer of a second oxide semiconductor different from the first oxide semiconductor, wherein the layered structure has one or more band gaps including a range of 1.3 eV to 1.5 eV.

### CROSS-REFERENCE TO RELATED APPLICATIONS

This application is based upon and claims the benefit of priority of the prior Japanese Patent Application No. 2016-011068 filed Jan. 22, 2016, which is incorporated herein by references in its entirety.

### FIELD

The present invention relates in general to a multilayer thin-film structure, a water splitting system using the multilayer thin-film structure, and a method of fabricating a multilayer-thin-film structure.

### BACKGROUND

Today energy use and conservation is of paramount importance. In place of conventional fossil fuel, renewable energy from natural resources such as solar energy or wind energy has been attracting considerable interest. Especially, there is presently a worldwide intensive research effort to harvest energy from the sun to convert to chemical fuels such as hydrogen (H₂) or hydrocarbons or to convert the solar energy to electrical energy which is subsequently stored in a battery. Upon absorption of the sun light, electron-hole pairs are produced, then separated under the action of a field, and the produced electrical energy can be stored in the form of a battery. Besides, water can be separated into oxygen and hydrogen by oxidation-reduction reactions under the presence of spatially separated electron-hole pairs to generate hydrogen fuel. In either cases, improvement of the energy conversion efficiency is important.

Semiconductor oxides including titanium oxide (TiO₂) or tin oxide (SnO₂) are employed as solar cells or catalysts for fuel cells to absorb the light and generate electrical energy. A technique of using a perovskite dielectric expressed by chemical formula ABO₃ for thin film capacitors is also known. See, for example, Japanese Patent Application Laid-open Publication No. 2005-259393. With this technique, a layer of SnO₂ and a layer of TiO₂ are deposited alternately and repeatedly such that each of the layers becomes a half of the unit lattice of the perovskite structure. Another known technique is to provide a pigment containing a SnO₂ layer and a TiO₂ layer. See, for example, Japanese National Publication of International Patent Application No. 2011-504193 (WO 2009/062886 A1).

### LIST OF PRIOR ART DOCUMENTS

Patent Document 1: JP 2005-259393 A

Patent Document 2: JP 2011-504193 A

### SUMMARY

For energy harvesting such as solar energy conversion, it is advantageous to use a material sensitive to the solar spectrum within the range of visible wavelengths. The present invention provides a multilayer thin-film structure that is sensitive to and enables absorption of light of visible range.

According to an aspect of the invention, a multilayer thin-film structure has a layered structure with an alternative stacking series of a first layer of a first oxide semiconductor and a second layer of a second oxide semiconductor different from the first oxide semiconductor, wherein the layered structure has one or more band gaps including a range of 1.3 eV to 1.5 eV.

The object and advantages of the invention will be realized and attained by means of the elements and combinations particularly pointed out in the claims. It is to be understood that both the foregoing general description and the following detailed description are exemplary and explanatory and are not restrictive to the invention as claimed.

### BRIEF DESCRIPTION OF DRAWINGS

FIG. 1 is a diagram illustrating the solar spectrum as well as absorption spectra of various semiconductor bulk materials;

FIG. 2 is a schematic diagram of a multilayer thin-film structure according to an embodiment;

FIG. 3 illustrates a band structure of BaSnO₃:

FIG. 4 illustrates a light absorption characteristic of LaBaSnO₃ of an indirect band gap type;

FIG. 5 illustrates a light absorption characteristic of a multilayer thin-film structure of an indirect band gap type, in comparison with that of LaBaSnO₃ of FIG. 4;

FIG. 6 illustrates a light absorption characteristic of a multilayer thin-film structure of a direct band gap type according to the embodiment, in comparison with that of LaBaSnO₃ of a direct band gap type;

FIG. 7 illustrates a light absorption characteristic of a multilayer thin-film structure of a direct band gap type according to the embodiment, in comparison with that of LaBaSnO₃ of an indirect band gap type;

FIG. 8 is an X-ray diffraction pattern through a range of 2θ diffraction angles;

FIG. 9 illustrates band gap tuning in the multilayer thin-film structure according to the embodiment;

FIG. 10 illustrates another example of a multilayer thin-film structure with a tailored visible range band gap; and

FIG. 11 is a schematic diagram of a water splitting system using a multilayer thin-film structure according to an embodiment.

### DESCRIPTION OF EMBODIMENTS

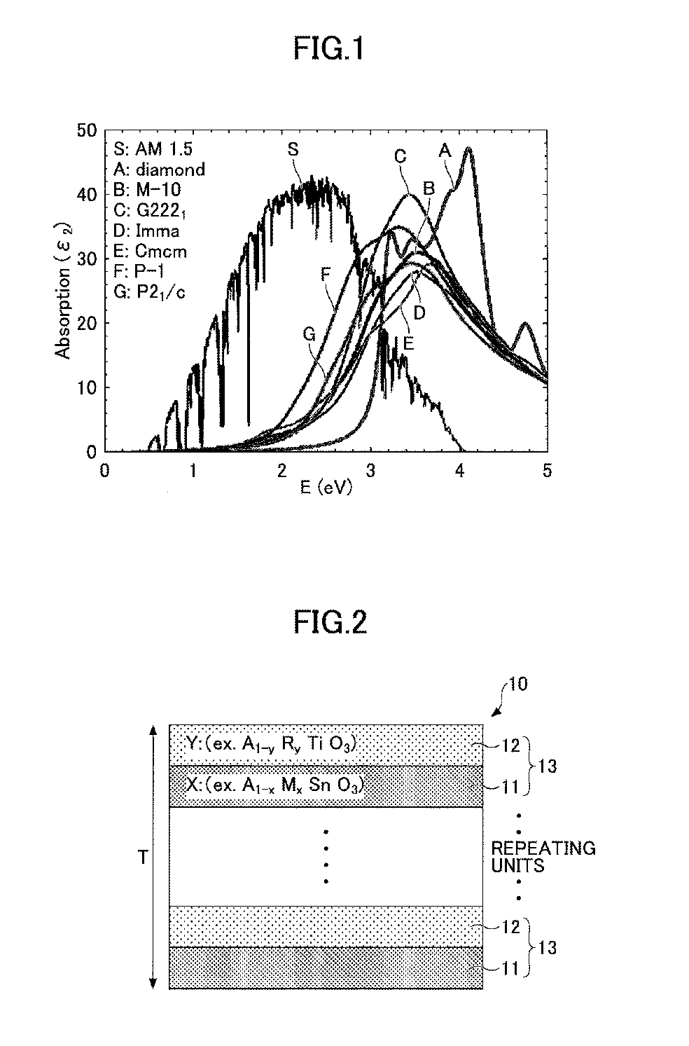

FIG. 1 illustrates an absorption spectrum of incoming solar radiation, together with absorption spectra of various semiconductor bulk materials. The spectrum S is the solar spectrum at air mass (AM) 1.5. The air mass represents the path length which light takes through the atmosphere normalized to the shortest possible path length and AM 1.5 means the path length 1.5 times longer than the shortest path at an incident angle of 90 degrees onto the earth surface. In other words, the path length of the sun light incoming at an incident angle of 41.8 degrees onto the earth surface.

As is understood from FIG. 1, sun light has a strong spectrum in the visible range with photon energies of 1.5 eV to 3.0 eV and the peak of its spectrum is near 2.0 eV to 2.5 eV (i.e., near green wavelengths). In the full solar spectrum, the visible range photon energy occupies 50% or more. Bulk TiO₂ or bulk SnO₂ typically used in a solar cell or a catalyst has a band gap as wide as 3.2 eV or more and visible rays of light transmit through such materials without absorption. By using a material sensitive to the solar spectrum ranging from 1.5 eV to 3.0 eV, more preferably from 1.3 eV to 3.2 eV, electron-hole pairs are produced effectively and high efficiency energy conversion can be achieved.

Meanwhile, when applying photovoltaics to harvesting hydrogen or chemical fuel through water splitting, it is desirable for a device to have an energy band structure that is suitable for oxidization and reduction as well as efficient photon absorption in the visible range.

As illustrated in FIG. 1, no semiconductor bulk material can accomplish photon absorption over the full solar spectrum so far. In FIG. 1, spectrum A represents photon absorption spectrum of diamond semiconductor, and spectra B to G represent photon absorption spectra of silicon-based semiconductor materials with sp3 hybrid orbitals of different phases. Because of small band gap values, silicon-based semiconductor bulk materials absorb visible range photon energies. However, such materials are of indirect transition types and not so sensitive to the solar spectrum of the visible range. Besides, ionization energy for oxidization-reduction (redox) potential is unsatisfactory.

In general, bulk materials with a narrow band gap capable of absorption of visible-range photon energies have a small (or narrow) depletion layer width. A depletion layer is required to separate the photon generated electron-hole pairs. Because of small depletion layers, the generated electron-hole pairs recombine and cannot be used for efficient energy harvesting. Hence, semiconductor bulk materials with band gaps sensitive to the visible range spectrum are limited owing to a relationship between the band gap and depletion layer width.

Band gap and depletion layer width can be adjusted to a certain extent by selecting materials and/or introducing dopants or defects in a bulk material. However, tunability through doping or defects is limited. Besides, not all materials are suitable for photo catalyst in terms of mobility, band alignments with redox (reduction-oxidation) level, or catalytic activity.

In view of the above-noted technical problems, the embodiments provide a multilayer thin-film structure sensitive to and that enables absorption of photon energies in a range of 1.3 eV to 3.2 eV. The embodiments also provide a structure with a tailored band gap or a continuously tunable band gap over a wide range.

FIG. 2 is a schematic diagram of a multilayer thin-film structure 10 according to an embodiment. By fabricating a heterostructure with periodic repetition of oxide layers of different materials, a multilayer thin-film structure 10 sensitive to and absorbing the solar spectrum of near-infrared and visible ranges can be achieved.

The multilayer thin-film structure 10 has a stacking structure of one or more composite layers 13, each of the composite layers 13 being formed of a first oxide semiconductor layer 11 (which may be called a “layer X”) and a second oxide semiconductor layer 12 (which may be called a “layer Y”). The first oxide semiconductor layer 11 and the second oxide semiconductor layer 12 are atomic level thin films made of different materials. By repeatedly stacking the first oxide semiconductor layer 11 and the second oxide semiconductor layer 12 in the form of atomic level thin films, superlattices can be produced and electron wave functions of the neighboring films overlap each other. A new electronic or energy band structure with a direct band gap that does not exist in the original crystal emerges.

The first oxide semiconductor layer 11 (i.e., layer X) is formed of a material that includes at least tin (Sn) and oxygen (O) and does not include titanium (Ti). Tin (Sn) has a low resistance and strong oxidation for holes. Examples of the material of the first oxide semiconductor layer 11 include a perovskite oxide expressed by A₁₋ₓMₓSnO₃ where element A is selected from a group of alkaline earth metals such as Sr, Ba, or Ca. Element M is selected from a group including La, Y, and Zr, such materials having a low temperature-dependency in thermal conductivity. As long as meeting with the conditions that at least elements Sn and O are included and that element Ti is excluded, ternary oxide compounds or binary oxide compounds (such as SnO₂) may be used.

The second oxide semiconductor layer 12 (i.e., layer Y) is formed of a material that includes at least titanium (Ti) and oxygen (O) and does not include tin (Sn). Titanium (Ti) has a low resistance and strong oxidation for holes. Examples of the material of the second oxide semiconductor layer 12 include a perovskite oxide expressed by A_{1-y}R_{y}TiO₃ where element A is selected from a group of alkaline earth metal such as Sr, Ba, or Ca. Element R is selected from a group including La, Y, and Zr. As long as meeting with the conditions that at least elements Ti and O are included and that element Sn is excluded, ternary oxide compounds or binary oxide compounds (such as TiO₂) may be used.

For example, the first oxide semiconductor layer 11 may be formed of LaBaSnO₃ with a thickness of 3 unit cells (u.c.), and the second oxide semiconductor layer 12 may be formed of LaSrTiO₃ with a thickness of 3 u.c.

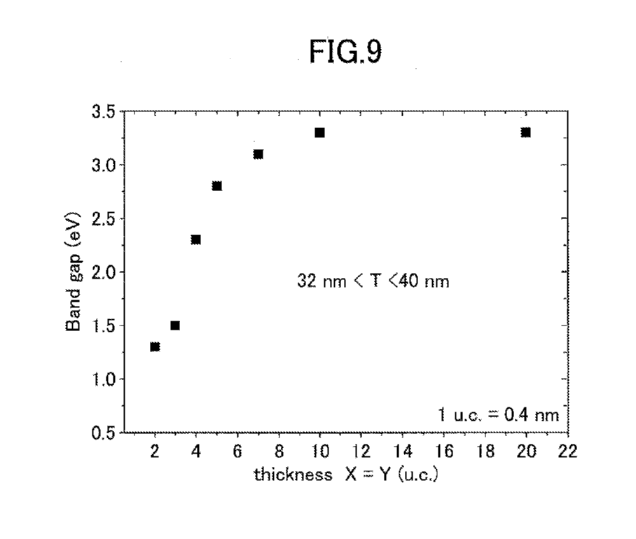

The thickness of the first oxide semiconductor layer 11 and the thickness of the second oxide semiconductor layer 12 may be selected in the range of 0.4 nm to 5 nm, or the range of 1 u.c. to 12 u.c. of a perovskite structure. With the thickness less than 0.4 nm or 1 u.c., it may become difficult to absorb a sufficient quantity of light. With the thickness greater than 5 nm or 12 u.c., band gap tunability does not increase any longer, while the internal stress of the thin film increases. As will be explained later in connection with FIG. 9, the band gap tunability by controlling film thickness is saturated in vicinity of 5 nm thickness of an oxide semiconductor film. Considering the band gap tunable range and reduction of internal stress of the thin film, it is desired that the thickness of each of the first oxide semiconductor layer 11 and the second oxide semiconductor layer 12 is within the range of 0.4 nm to 5 nm.

The thicknesses of the first oxide semiconductor layer 11 and the second oxide semiconductor layer 12 may be the same or different from each other. As long as a periodic stacking structure with repetitions of alternating film deposition is acquired, the first oxide semiconductor layer 11 is not necessarily the lowermost layer. Although the multilayer thin-film structure 10 illustrated in FIG. 2 is designed so as to have fifteen repeating units (by forming a composite layer 13 fifteen times) with the total thickness T of 36 nm, the invention is not limited to this example. Any suitable number of repeating units such as 30 repeating units or 60 repeating units may be selected. The thickness of at least one of the first oxide semiconductor layer 11 and the second oxide semiconductor layer 12 may be varied in the stacking structure. By changing the thickness of the first oxide semiconductor layer 11 and/or the second oxide semiconductor layer 12 in the stacking structure, the energy band gap can be tuned and efficient light absorption is achieved in the visible range.

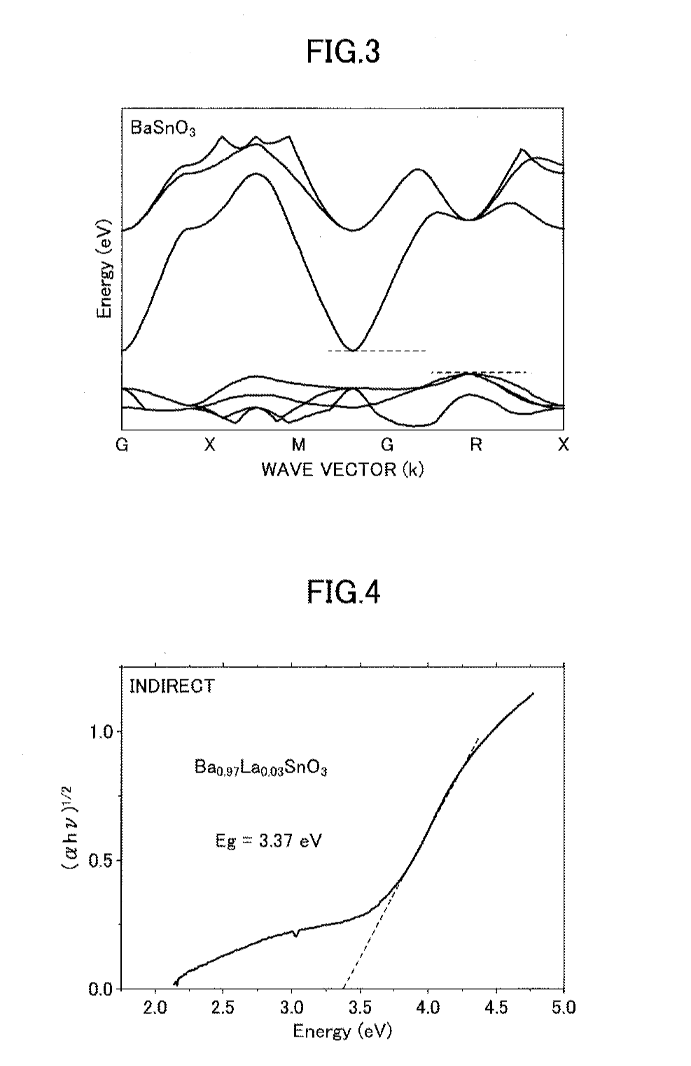

FIG. 3 illustrates a band structure of BaSnO₃ as an example of perovskite oxides. The horizontal axis represents wave vector (k), and the vertical axis represents energy. Different electronic band configurations are included depending on electrons behaving as waves in crystalline solid. As illustrated in FIG. 3, BaSnO₃ is an indirect band gap material in a bulk form, where the top of the valence band and the bottom of the conduction band are not vertically aligned in the wave space (k space). Other perovskite semiconductors including SrSnO₃, SrTiO₃, CaTiO₃ and LaBaSnO₃ are also indirect materials in bulk form.

FIG. 4 illustrates optical absorption of Ba_{0.97}La_{0.03}SnO₃, which compound is used as an example of the first oxide semiconductor layer 11. The optical absorption of FIG. 4 is plotted assuming an indirect band-gap model. The horizontal axis represents photon energy and the vertical axis represents (αhν)^{1/2}, where α denotes absorption coefficient. The band gap of Ba_{0.97}La_{0.03}SnO₃ calculated from change in the absorption coefficient is as wide as 3.37 eV. The curve appearing in the energy range below 3.5 eV is background noise.

As illustrated in the simulation result of FIG. 4, Ba_{0.97}La_{0.03}SnO₃ by itself absorbs only light of ultraviolet wavelengths. Similarly, LaSrSnO₃ used as the first oxide semiconductor and LaSrTiO₃ used as the second oxide semiconductor have their fundamental absorption above 3 eV in a single bulk form.

FIG. 5 illustrates optical absorption of the layered structure (or the superlattice heterostructure) of FIG. 2 with a SrLaTiO₃ (abbreviated as “SLTO”) film of 3 unit cells stacked over a BaLaSnO₃ (labeled as “BLSO”) film of 3 unit cells. The data are plotted assuming an indirect gap. For the comparison purpose, the optical absorption spectrum of a BLSO reference sample of FIG. 4 in a single bulk form is presented together with the optical absorption of the LSTO/BLSO heterostructure. The materials of the first oxide semiconductor layer 11 and the second oxide semiconductor layer 12 have a wide band gap as in a single bulk form. In contrast, by alternately and repeatedly stacking the first oxide semiconductor layer 11 and the second semiconductor layer 12 in forms of thin films, optical absorption covers the range from 1.5 eV to 2.7 eV.

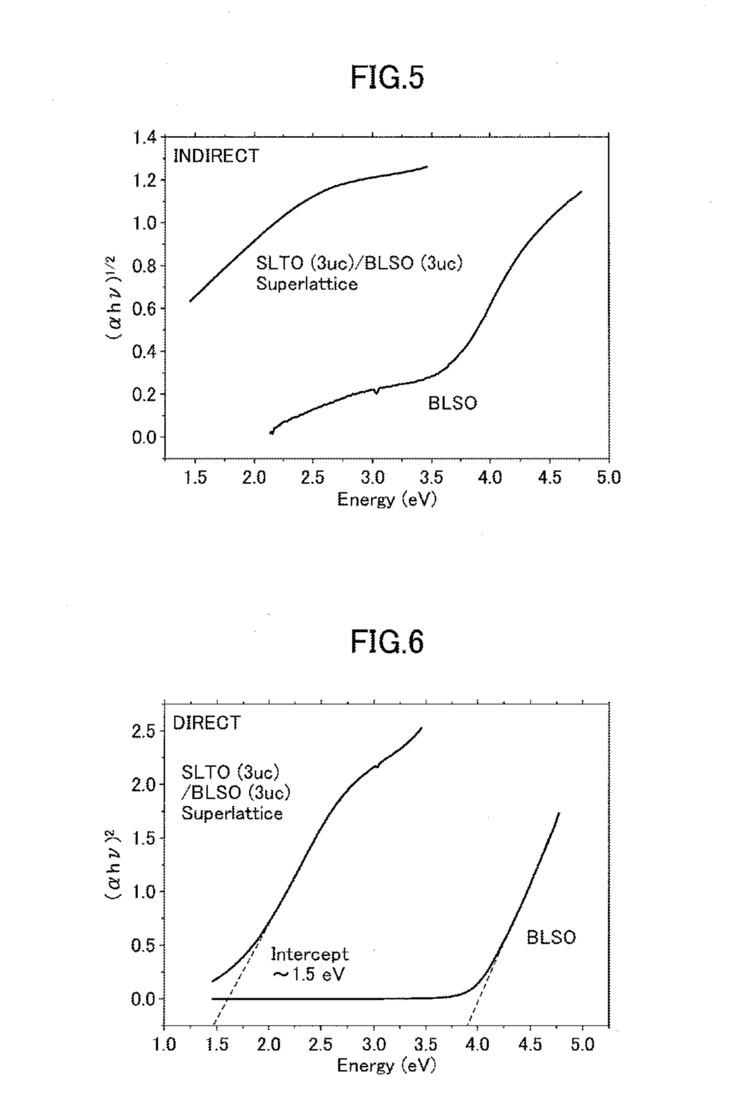

FIG. 6 illustrates optical absorption of the superlattice structure (SLTO (3 uc)/BLSO (3 uc)) of FIG. 2, together with optical absorption of Ba_{0.97}La_{0.03}SnO₃ (labeled as “BLSO”). The data are plotted assuming a direct gap. The horizontal axis represents photon energy and the vertical axis represents (αhν)². In case of a direct gap model, electrons in the valence band are excited directly into the conduction band. The superlattice structure of SLTO (with 3 unit-cell thickness) over BLSO (with 3 unit-cell thickness) has an optical absorption characteristic covering a range from 1.5 eV to 3 eV, which characteristic has good consistency with the solar spectrum.

BaLaSnO (abbreviated as “BLSO”) and SrLa TiO (abbreviated as “SLTO”) have similar band structures, in which materials lanthanum ions having a low hole mobility (at or less than 50 cm²/Vs) are doped. These materials have similar carrier densities commensurate with the La doping density. Accordingly, the same simulation result is expected for other superlattice structures, such as BLSO/SLTO, SLSO/SLTO, etc.

In a direct gap model, electron are excited solely by photon energy into the conduction band and optical absorption is large compared with an indirect gap model. The (αhν)² value (in the vertical axis of FIG. 6) increases in the region over 2.2 eV (in and above green region) and solar spectrum absorption efficiency is satisfactory. By efficiently separating electrons and holes created by optical absorption, highly efficient solar energy conversion can be realized. By providing an appropriate oxidation/reduction system, hydrogen fuel can be produced efficiently.

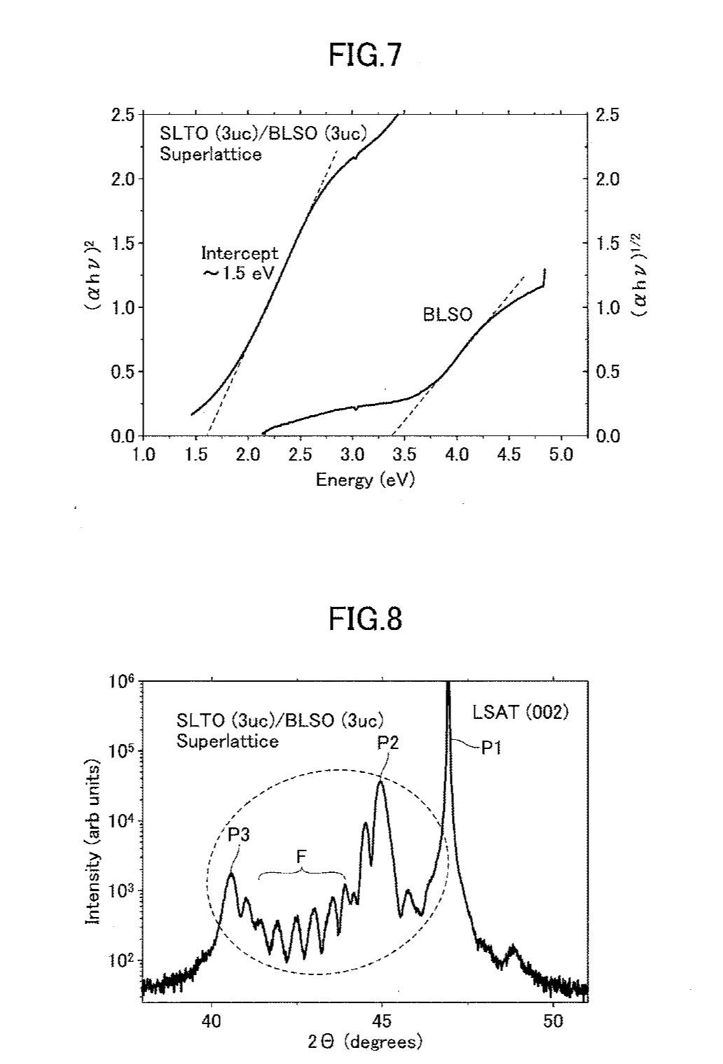

FIG. 7 illustrates optical absorption of SLTO (3 uc)/BLSO (3 uc) superlattice of a direct gap model, together with optical absorption of BLSO of an indirect gap model. BLSO is fundamentally an indirect gap material. An oxide semiconductor in a single bulk form cannot efficiently absorb the solar spectrum in the visible range. In contrast, when two oxide semiconductor thin films are combined on an atomic level to produce a superlattice or a hetero structure, optical absorption matching with the visible range solar spectrum can be achieved.

FIG. 8 illustrates θ-2θ X-ray diffraction (XRD) pattern of the SLTO (3 uc)/BLSO (3 uc) superlattice. A sample was prepared by forming a Ba_{0.95}La_{0.05}SnO₃ layer of 3 unit cell thickness and a Sr_{0.95}La_{0.05}TiO₃ layer with 3 unit cell thickness alternately, repeating 15 times, over an (La, Sr) (Al, Ta)O₃ substrate (abbreviated as “LSAT” substrate).

The peak P1 represents (002) diffraction peak of the LSAT substrate. The peak P2 represents a main peak of the SLTO/BLSO superlattice, and the peak P3 represents a satellite peak of the SLTO/BLSO superlattice. In the region surrounded by the dashed line, many flanges F appear between P2 and P3 periodically, which spectrum indicates production of superlattice. This superlattice structure provides the SLTO/SLSO layered structure with satisfactory absorption sensitivity to visible light and large optical absorption.

FIG. 9 illustrates band gap tuning of the periodic layered structure according to the embodiment. The horizontal axis represents thickness (u.c.) of an oxide semiconductor layer and the vertical axis represents band gap energy (eV). In this figure, one unit cell of the perovskite structure is 0.4 nm. The total thickness T of the multilayer thin-film structure 10 of FIG. 2 is fixed to 36 nm, while the thicknesses of the layer X (formed of LaBaSnO₃ in this experiment) and layer Y (formed of LaSrTiO₃ in this experiment) are varied, to measure the band gap energy of the entirety of the periodic layered structure. Considering an error in the number of repeating units (that is an integer) caused by changing the film thickness, the error range of the total thickness T is set to 32 nm<T<40 nm. It is assumed that the thicknesses of layer X and layer Y are the same in this experiment.

When the thickness of layer X and layer Y is 2 unit cells (0.8 nm), the thickness of the composite layer 13 is 1.6 nm and the number of repeating units of FIG. 2 is 22 or 23. The band gap energy of the multilayer thin-film structure is 1.3 eV. With this tailoring, photon energy at or higher than 1.3 eV (corresponding to wavelengths of or shorter than near infrared rays) can be absorbed. Because of small band gap, optical absorption for visible light is satisfactory.

When the thickness of layer X and layer Y is set to 3 unit cells (1.2 nm), the thickness of the composite layer 13 is 2.4 nm and the number of repeating units is 15. The band gap energy of the multilayer thin-film structure 10 is 1.5 eV, and visible light with photon energy at or higher than 1.5 eV can be absorbed. With this tailoring, redox (oxidation-reduction) potential relevant to the valence band and conduction band energy levels is improved, compared with the 2-unit-cell thickness configuration.

When the thickness of layer X and layer Y is set to 4 unit cells (1.6 nm), the thickness of the composite layer 13 is 3.2 nm and the number of repeating units is 11. With this tailoring, the band gap energy of the multilayer thin-film structure 10 is 2.3 eV, and green wavelengths including the peak wavelength of the solar spectrum can be absorbed effectively. Besides, satisfactory redox potential determined from the valence and conduction band energy levels can be acquired.

As increasing the thickness of layer X and layer Y to 5 unit cells, 7 unit cells, 10 unit cells, etc., the band gap energy increases. Above 12 unit cells of the film thickness, the band gap energy saturates at 3.2 eV. Because of the wide band gap, the valence band and conduction band potential levels exhibit strong redox ability; however, visible light transmits through without absorption.

In view of the band gap tuning range of superlattice and influence of internal stress, it is preferable for at least one of layer X and layer Y that the film thickness is in the range of 1 unit cell (0.4 nm) to 12 unit cells (5 nm), and more preferably, from 2 unit cells (0.8 nm) to 10 unit cells (4 nm).

The thickness of at least one of layer X and layer Y may be varied in a continuous or stepwise manner, thereby changing the band gap continuously or step by step. The thickness ratio of layer X to layer Y in the composite layer 13 may be adjusted, such as 50 to 50, 60 to 40, or 40 to 60 in percentage, thereby tuning the band gap. By controlling the thickness of at least one of the first oxide semiconductor layer (or layer X) and the second oxide semiconductor layer (or layer Y) of the multilayer thin-film structure 10, multiple band gaps can be produced and the solar spectrum of the visible range over 1.5 eV to 3.0 eV can be absorbed efficiently.

The above-described relationship between the film thickness and band gap energy apples to multilayer thin-film structures using other quaternary perovskite oxides or ternary perovskite oxides.

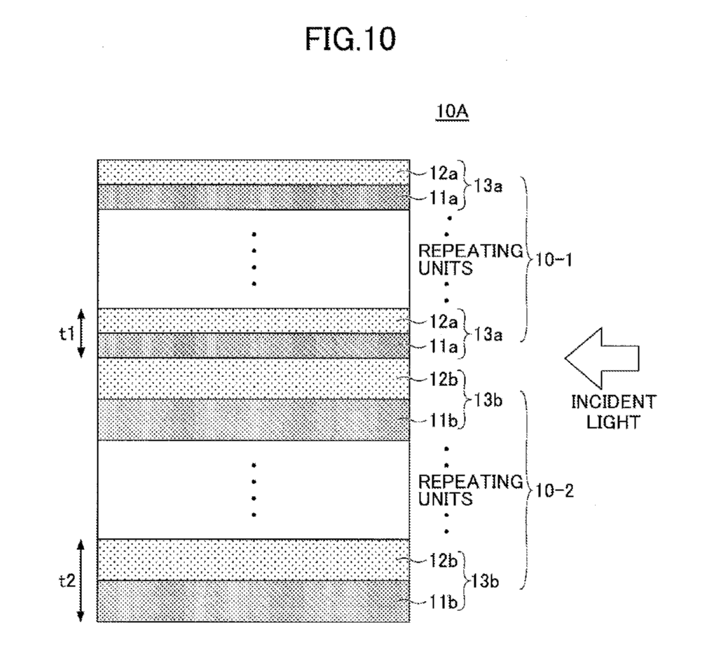

FIG. 10 illustrates a multilayer thin-film structure 10A with a layered structure with variable film thickness. The multilayer film structure 10A has a first layered structure 10-1 and a second layered structure 10-2. The first layered structure 10-1 includes first oxide semiconductor layers 11a and second oxide semiconductor layers 12a of a first film thickness stacked alternately and repeatedly. The second layered structure 10-2 includes first oxide semiconductor layers 11b and second oxide semiconductor layers 12b of a second film thickness stacked alternately and repeatedly.

In the first layered structure 10-1, multiple composite layers 13a, each composite layer having thickness t1, are stacked. In the second layered structure 10-2, multiple composite layers 13b, each composite layer having thickness t2, are stacked. The layered structures may be tailored such that, for instance, the thickness of the first oxide semiconductor layer 11a and the second oxide semiconductor layer 12a is set to 3 unit cells and that the thickness of the first oxide semiconductor layer 11b and the second oxide semiconductor layer 12b is set to 4 unit cells. With this arrangement, the solar spectrum can be absorbed efficiently from red region to green region, and satisfactory redox potential can be achieved. Although not illustrated, a third layered structure with alternate stacking series of the first oxide semiconductor layer 11 and the second oxide semiconductor layer 12 with a third film thickness (e.g., 5 unit cells) may be added. In this case, the solar spectrum over the entire visible range can be absorbed, while maintaining suitable redox potential level.

### EXAMPLE 1

An alternative stacking series with a first oxide semiconductor layer 11 (layer X) and a second oxide semiconductor layer 12 (layer Y) is repeated 15 times over an insulating LSAT(001) substrate. Here X is Ba_{0.95}La_{0.05}SnO₃ and Y is Sr_{0.95}La_{0.05}TiO₃. Layer X and layer Y are deposited using a suitable deposition method, such as RF magnetron sputtering or pulse laser deposition (PLD). In Example 1, the thickness of layer X (Ba_{0.95}La_{0.05}SnO₃) and the thickness of layer Y (Sr_{0.95}La_{0.05}TiO₃) are both 1.2 nm. A total of 15 repeating units of layer X and layer Y were deposited for a total thickness of 36 nm. The optical absorption characteristics acquired by the oxide heterostructure of Example 1 are illustrated in FIG. 5 (assuming an indirect gap model) and FIG. 6 (assuming a direct gap model), both exhibiting optical absorbance from 1.5 eV to 3 eV.

### EXAMPLE 2

An alternative stacking series with a first oxide semiconductor layer 11 (layer X) and a second oxide semiconductor layer 12 (layer Y) is repeated 30 times over an insulating LSAT(001) substrate. Here X is Ba_{0.90}La_{0.10}SnO₃ and Y is Sr_{0.90}La_{0.10}TiO₃. Layer X and layer Y are deposited using a suitable deposition method, such as RF magnetron sputtering or pulse laser deposition (PLD). In Example 2, the thickness of layer X (Ba_{0.90}La_{0.10}SnO₃) and the thickness of layer Y (Sr_{0.90}La_{0.10}TiO₃) are both 1.2 nm. A total of 30 repeating units of layer X and layer Y were deposited for a total thickness of 72 nm. This sample also exhibits satisfactory optical absorbance in the visible range of 1.5 eV to 3.0 eV, as illustrated in FIG. 5 and FIG. 6. With the increased thickness of the multilayer thin-film structure, optical absorbance is further improved and solar electric energy conversion efficiency rises.

### EXAMPLE 3

An alternative stacking series with a first oxide semiconductor layer 11 (layer X) and a second oxide semiconductor layer 12 (layer Y) is repeated 60 times over a conducting Nb doped SrTiO₃ substrate. Here X is Ba_{0.90}La_{0.10}SnO₃ and Y is Sr_{0.90}La_{0.10}TiO₃. Layer X and layer Y are deposited using a suitable deposition method, such as RF magnetron sputtering or pulse laser deposition (PLD). In Example 3, the thickness of layer X (Ba_{0.90}La_{0.10}SnO₃) and the thickness of layer Y (Sr_{0.90}La_{0.10}TiO₃) are both 1.2 nm. A total of 60 repeating units of layer X and layer Y were deposited for a total thickness of 144 nm. This sample also exhibits satisfactory optical absorbance in the visible range of 1.5 eV to 3.0 eV, as illustrated in FIG. 5 and FIG. 6, with further increased solar energy conversion efficiency.

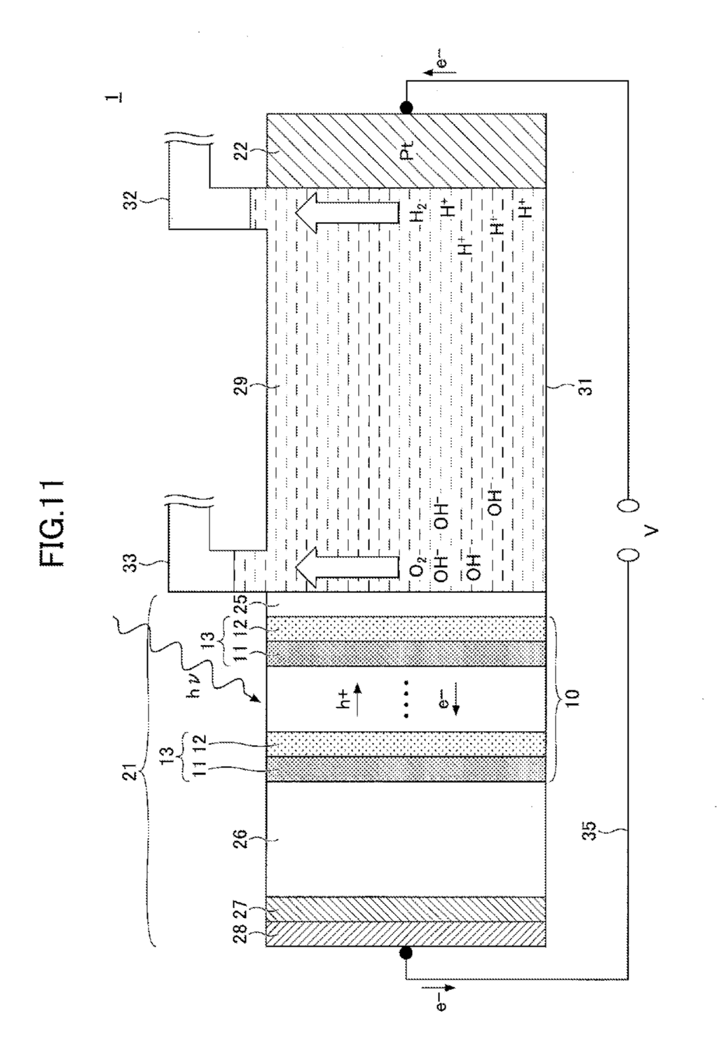

FIG. 11 is a schematic diagram of a water splitting system 1 using the multilayer thin-film structure 10 of FIG. 2 as a photo electrode. The water splitting system 1 has an anode electrode 21 and a cathode electrode 22 arranged facing each other, and an electrolyte solution 29 is provided between the anode electrode 21 and the cathode electrode 22. The electrolyte 29 is accommodated in, for example, a chamber 31.

The anode electrode 21 has an oxygen evolution reaction (OER) catalyst 25, the multilayer thin-film structure 10 serving as a photo anode, a substrate 26, a metal layers 27 and 29 arranged in this order from the interface with the electrolyte solution 29. The OER catalyst 26 produces oxygen gas from water, and iridium oxide (IrOₓ) with thickness of 100 nm is used as the catalyst in this example.

The multilayer thin-film 10 serving as the photo anode is formed on one side of the substrate 26, which substrate is, for example, a 2 at % Nb doped SrTiO₃ (Nb:SrTiO₃) substrate with a thickness of 0.5 mm. The substrate is conducting because of doped niobium. The multilayer thin-film structure 10 is made of an alternative stacking series with a first oxide semiconductor layer 11 of 1.2 nm thickness and a second oxide semiconductor layer 12 of 1.2 nm thickness repeated 30 times over the substrate 26. The total thickness of the multilayer thin-film structure 10 is 72 nm. The first oxide semiconductor layer 11 (or layer X) is formed of a material that includes at least elements tin (Sn) and oxygen (O) and does not include titanium (Ti). The second oxide semiconductor layer 12 (or layer Y) is formed of a material that includes at least elements titanium (Ti) and oxygen (O) and does not include tin (Sn).

In place of the multilayer thin-film structure 10, a multilayer thin film structure 10A illustrated in FIG. 10 in which structure the thickness of at least one of the first oxide layer 11 and the second oxide layer 12 is variable. Using the multilayer thin-film structure 10A as a photo electrode, sufficient optical absorption in the visible range and satisfactory oxidation-reduction ability are acquired.

On the other side of the substrate 26 are formed the metal layers 27 and 28. The metal layer 27 is formed of, for example, chromium (Cr), cobalt (Co), nickel (Ni), tantalum (Ta) or any other suitable metal. In this example, the metal layer 27 is a Cr layer with a thickness of 25 nm. The metal layer 29 is formed of a good conductor such as gold (Au), silver (Ag), platinum (Pt), etc. In this example, the metal layer 28 is an Au layer.

The cathode electrode 22 is formed of, for example, platinum (Pt), iridium (Ir), palladium (Pd), or any other suitable material. In this example, a Pt film with a thickness of 0.5 mm is used as the cathode electrode 22.

Upon incidence of photons with energy (hν) equal to or greater than the band gap of the multilayer thin-film structure 10 onto the anode electrode 21, the photons are absorbed and electrons (e−) and holes (h+) are produced. Under the application of an electric field, the holes move to the OER catalyst 25, while the electrons move toward the metal layer 28 and reach the cathode electrode 22 through the wiring 35.

In the electrolyte solution 29, hydrogen and oxygen are produced by oxidation-reduction reaction of water due to the electrons and the holes. Generation of hydrogen gas is expressed by reaction 2H₂O+2e−→H₂+2OH−. Through the reduction process of electrons, hydrogen gas and hydroxyl (OH−) are produced. The produced hydrogen gas is collected in a container by a hydrogen tube 32. The hydroxyl (OH−) is attracted to the anode electrode 21.

Generation of oxygen is expressed by reaction 4OH−→O₂+2H₂O+4e−. Through the oxidation process by the holes having reached the surface of the OER catalyst 25, oxygen gas is produced. The produced oxygen gas is discharged or collected through an oxygen tube 33.

Because the multilayer thin-film structure 10 with tailored ban gap(s) achieving high absorbance to the visible range solar spectrum and suitable for oxidation and reduction is used as the photo electrode, hydrogen gas can be produced effectively with high conversion efficiency of the photovoltaic cell.

The multilayer thin-film structures 10 and 10A of the embodiment are applicable to other light to electric energy conversion devices such as a solar cell. In such application, the first oxide layer 11 with a thickness of 0.4 nm to 5 nm (or 1 unit cell to 12 unit cell) and the second oxide layer 12 with a thickness of 0.4 nm to 5 nm (or 1 unit cell to 12 unit cell) are deposited alternately and repeatedly. During the alternative stacking of layers, the thickness of at least one of the first oxide semiconductor layer 11 and the second oxide semiconductor layer 12 may be varied.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of superiority or inferiority of the invention. Although the embodiments of the present inventions have been described in detail, it should be understood that the various changes, substitutions, and alterations could be made hereto without departing from the spirit and scope of the invention.

What is claimed is:

1. A multilayer thin-film structure comprising:
a layered structure with an alternative stacking series of a first layer of a first oxide semiconductor and a second layer of a second oxide semiconductor different from the first oxide semiconductor,
wherein the layered structure has one or more band gaps including a range of 1.3 eV to 1.5 eV.

2. The multilayer thin-film structure as claimed in claim 1,
wherein a thickness of the first layer and a thickness of the second layer are within a range of 0.4 nm to 5 nm or a range of 1 unit cell to 12 unit cells.

3. The multilayer thin-film structure as claimed in claim 1, wherein
the first oxide semiconductor includes at least elements Sn and O and does not include Ti, and
the second oxide semiconductor includes at least elements Ti and O and does not include Sn.

4. The multilayer thin-film structure as claimed in claim 3, wherein
the first oxide semiconductor is a perovskite oxide with a general formula of A₁₋ₓMₓSnO₃, where A is selected from a group of Sr, Ba, and Ca.

5. The multilayer thin-film structure as claimed in claim 4, wherein in the perovskite oxide with the general formula of A₁₋ₓMₓSnO₃, M is selected from a group of La, Y, and Zr.

6. The multilayer thin-film structure as claimed in claim 3, wherein
the first oxide semiconductor is a perovskite oxide with a general formula of A₁₋ₓMₓSnO₃, where M is selected from a group of La, Y, and Zr.

7. The multilayer thin-film structure as claimed in claim 3, wherein
the second oxide semiconductor is a perovskite oxide with a general formula of A_{1-y}R_{y}TiO₃, where A is selected from a group of Sr, Ba, and Ca.

8. The multilayer thin-film structure as claimed in claim 7, wherein in the perovskite oxide with the general formula of A_{1-y}R_{y}TiO₃, R is selected from a group of La, Y, and Zr.

9. The multilayer thin-film structure as claimed in claim 3, wherein
the second oxide semiconductor is a perovskite oxide with a general formula of A_{1-y}R_{y}TiO₃, where R is selected from a group of La, Y, and Zr.

10. The multilayer thin-film structure as claimed in claim 1, wherein the layered structure include
a first layered structure having a first composite layer of a first thickness, the first composite layer including the first layer and the second layer formed over the first layer, and
a second layered structure having a second composite layer of a second thickness, the second composite layer including the first layer and the second layer formed over the first layer,
wherein at least one of the first layer and the second layer of the second composite layer has a thickness different from that of the first layer or the second layer of the first composite layer.

11. The multilayer thin-film structure as claimed in claim 1, wherein a thickness ratio of the first layer to the second layer is variable in the layered structure.

12. A solar energy converting device using the multilayer thin-film structure as claimed in claim 1.

13. A water splitting system comprising:
a first electrode having a multilayer thin-film structure with a photo-absorption sensitivity in a range of 1.3 eV to 3.0 eV, the multilayer thin-film structure including an alternative stacking series of a first oxide semiconductor layer and a second oxide semiconductor layer made of a different material from the first oxide semiconductor layer;
a second electrode facing the first electrode; and
an electrolyte provided between the first electrode and the second electrode.

14. The water splitting system as claimed in claim 13, further comprising:
a chamber configured to accommodate the electrolyte,
wherein the chamber has a first tube configured to collect hydrogen on a side of the second electrode.

15. The water splitting system as claimed in claim 14,
wherein the chamber has the second tube configured to collect oxygen on a side of the first electrode.

16. The water splitting system as claimed in claim 13, further comprising:
a chamber configured to accommodate the electrolyte,
wherein the chamber has a second tube configured to collect oxygen on a side of the second electrode.

17. A method for fabricating a multilayer thin-film structure, comprising:
forming a first oxide semiconductor layer having a thickness within a range of 0.4 nm to 5 nm or a range of 1 unit cell to 12 unit cells,
forming a second oxide semiconductor layer over the first oxide semiconductor layer, the second oxide semiconductor layer having a thickness within a range of 0.4 nm to 5 nm or a range of 1 unit cell to 12 unit cells; and
repeating stacking of the first oxide semiconductor layer and second oxide semiconductor layer multiple times.
